(19) United States
(12) Patent Application Publication
(10) Pub. No.: US 2013/0113695 A1
(43) Pub. Date: May 9, 2013

(54) DISPLAY DEVICE

(71) Applicants: Wen-Hsien Tseng, Taichung City (TW); Yen-Heng Huang, New Taipei City (TW); Chia-Hui Pai, Taichung City (TW); Chung-Kai Chen, Taichung City (TW); Wei-Yuan Cheng, Taichung City (TW); Ming-Yung Huang, Changhua County (TW)

(72) Inventors: Wen-Hsien Tseng, Taichung City (TW); Yen-Heng Huang, New Taipei City (TW); Chia-Hui Pai, Taichung City (TW); Chung-Kai Chen, Taichung City (TW); Wei-Yuan Cheng, Taichung City (TW); Ming-Yung Huang, Changhua County (TW)

(73) Assignee: Au Optronics Corporation, Hsinchu (TW)

(21) Appl. No.: 13/443,901

(22) Filed: Apr. 11, 2012

(30) Foreign Application Priority Data
Nov. 8, 2011 (TW) 100140694

(51) Int. Cl. G09G 3/36; H01L 33/08

(52) U.S. Cl. 345/92; 257/88; 257/E33.012

(57) ABSTRACT

A display device includes a first panel and a second panel stacked together. The first panel includes a first active region, a first peripheral region, a first substrate, a second substrate, a display medium, a pixel array integrated with a color filter film, a common electrode, and a first light shielding layer. The second panel includes a second active region, a second peripheral region, a third substrate, an element layer, and a second light shielding layer disposed in the second peripheral region. The first light shielding layer includes first light shielding patterns leaning against the pixel array and the common electrode and second light shielding patterns forming a black matrix in the first active region. The second light shielding patterns are shorter than the first light shielding patterns. The second active region is smaller than, the first active region. The second peripheral region is larger than the first peripheral region.

### CROSS-REFERENCE TO RELATED APPLICATION

This application claims the priority benefit of Taiwan application serial no. 100140694, filed on Nov. 8, 2011. The entirety of the above-mentioned patent application is hereby incorporated by reference herein and made a part of this specification.

### BACKGROUND OF THE INVENTION

1. Field of the Invention

The invention generally relates to a display device, and more particularly, to a display device constituted by two panels with different functions.

2. Description of Related Art

In the existing liquid crystal display (LCD) panel, a color filter film can be directly formed on a pixel array (color filter on array, COA), and so can a black matrix (black matrix on array, BOA). Specifically, a pixel array substrate having the color filter film or the black matrix is assembled to an opposite substrate, and liquid crystal molecules are trapped between the two substrates to form the LCD panel.

Moreover, in the LCD panel, the black matrix located in an active region (i.e., a display region), spacers that allow the cell gaps to remain uniform, and light shielding patterns that are located in a peripheral region and shield transmission wires can be made of the same material and by the same manufacturing steps, so as to simplify the overall fabrication process. For instance, components including the black matrix, the spacers, and the light shielding patterns can be substantially made of a photosensitive material and formed by performing a photolithography process.

However, the area occupied by the light shielding patterns in the peripheral region is greater than the area occupied by the black matrix and the spacers. In the same photolithography process, controlling the height of the light shielding patterns occupying a large area of the peripheral region is more difficult than controlling the height of the black matrix and the spacers. In a COA design, the light shielding patterns in the peripheral region need be partially overlapped with the pixel array having the color filter film thereon, i.e., the light shielding patterns need be overlapped with the edge of the active region, so as to hide the conductive wires in the peripheral region and prevent unnecessary light leakage on the edge of the active region. At this time, the height of the light shielding patterns may be greater than that of the spacers, such that uniform cell gaps in the LCD panel cannot be provided, and that quality of the LCD panel is not in general satisfactory.

### SUMMARY OF THE INVENTION

The invention is directed to a display device in which a display panel and another panel with a different function are integrated to provide multiple functions, and thus the display panel can have favorable quality.

In the invention, a display panel that includes a first panel and a second panel stacked on the first panel is provided. The first panel has a first active region and a first peripheral region that surrounds the first active region. In addition, the first panel includes a first substrate, a second substrate, a display medium, a pixel array, a color filter film, a common electrode, and a first light shielding layer. The second panel has a second active region and a second peripheral region that surrounds the second active region. Besides, the second panel includes a third substrate, an element layer, and a second light shielding layer. In the first panel, the second substrate is opposite to the first substrate in a top-bottom manner, and the display medium is sandwiched between the first substrate and the second substrate. The pixel array is disposed on the first substrate and located between the first substrate and the display medium for driving the display medium. The color filter film is combined with the pixel array. The common electrode is disposed on the second substrate and located between the display medium and the second substrate. The first light shielding layer is disposed between the first substrate and the second substrate. Besides, the first light shielding layer includes a plurality of first light shielding patterns and a plurality of second light shielding patterns. The second light shielding patterns are located in the first active region and form a black matrix. The first light shielding patterns substantially lean against the pixel array and the common electrode. The second light shielding patterns are shorter in height than the first light shielding patterns. The second active region is substantially smaller in area than the first active region, and the second peripheral region is substantially larger in area than the first peripheral region. The third substrate is opposite to the second substrate, and the element layer is disposed between the third substrate and the second substrate. The second light shielding layer is disposed in the second peripheral region.

According to an embodiment of the invention, a projection area of the second light shielding layer on the first panel is overlapped with an edge of the first active region.

According to an embodiment of the invention, the second light shielding layer includes a light shielding ring that surrounds the second active region.

According to an embodiment of the invention, the pixel array includes a plurality of scan lines, a plurality of data lines, a plurality of active devices, and a plurality of pixel electrodes. The scan lines and the data lines are intersected. Each of the active devices is connected to a corresponding one of the scan lines and a corresponding one of the data lines. Each of the pixel electrodes is connected to a corresponding one of the scan lines and a corresponding one of the data lines through one of the active devices. The black matrix is located above the scan lines, the data lines, and the active devices.

According to an embodiment of the invention, the first light shielding layer further includes a plurality of discontinuous third light shielding patterns located in the first peripheral region, and the third light shielding patterns and the second light shielding layer are overlapped.

According to an embodiment of the invention, the first light shielding layer further includes a third light shielding pattern located in the first peripheral region.

According to an embodiment of the invention, the first light shielding layer is disposed on the first substrate, such that the second light shielding patterns are located between the display medium and the pixel array.

According to an embodiment of the invention, the first light shielding layer is disposed on the second substrate, such that the second light shielding patterns are located between the display medium and the common electrode.

According to an embodiment of the invention, the element layer of the second panel includes a touch sensing layer or a parallax barrier layer.

According to an embodiment of the invention, the second panel further includes a fourth substrate opposite to the third substrate, and the fourth substrate is located between the element layer and the second substrate of the first panel.

Based on the above, the first panel having the display function and the second panel having a different function are stacked together in the invention, so as to allow the display device to provide functions other than the function of displaying two-dimensional images, such as a function of displaying stereoscopic images, a touch sensing function, and so forth. The first panel having the display function is characterized by the COA structure. The light shielding layer in the second panel featuring another function can at least cover the peripheral region and the edge of the active region of the first panel. Thereby, the light shielding layer occupying a large area of the peripheral region of the first panel need not be overlapped with the active region, and the light leakage on the edge of the active region can still be prevented. As such, the satisfactory quality of the first panel in the display device can be promised.

In order to make the aforementioned and other features and advantages of the invention more comprehensible, embodiments accompanying figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the invention.

FIG. 1 is a top view illustrating a display device according to an embodiment of the invention.

FIG. 2 is a cross-sectional view illustrating the display device depicted in FIG. 1 along a sectional line I-I′ according to a first embodiment of the invention.

FIG. 3 is a cross-sectional view illustrating the display device depicted in FIG. 1 along a sectional line I-I′ according to a second embodiment of the invention.

FIG. 4 is a cross-sectional view illustrating the display device depicted in FIG. 1 along a sectional line I-I′ according to a third embodiment of the invention.

FIG. 5 is across-sectional view illustrating the display device depicted in FIG. 1 along a sectional line I-I′ according to a fourth embodiment of the invention.

FIG. 6 is a cross-sectional view illustrating the display device depicted in FIG. 1 along a sectional line I-I′ according to a fifth embodiment of the invention.

### DESCRIPTION OF EMBODIMENTS

The demand for display quality of display devices continues to grow in recent years. Apart from requirements for high image resolution and high color saturation, displays capable of displaying stereoscopic images have been developed in order to satisfy the need of users. Besides, in many electronic products, a touch sensing design is integrated into a display panel, so as to expand the area where the screen is disposed by removing the space for placing the keyboard or the operation buttons.

Generally, a display panel and a parallax barrier panel are required to be stacked together in order for a display device to display stereoscopic images; likewise, a display panel and a touch sensing panel are required to be stacked together in order for a display device to have a touch sensing function. Since conductive wires for signal transmission are inevitably disposed in peripheral regions of all the three panels described above, light shielding patterns or films are formed on the peripheral regions of the panels to conceal the conductive wires that may leave an adverse impact on the overall appearance of the display device. The light shielding patterns are also required by the display panel for preventing unnecessary light leakage on the edge of the active region to achieve satisfactory display effects.

Nonetheless, in the display panel with the COA structure, the light shielding patterns occupying a large area are overlapped with the pixel array that is integrated with a color filter film, which leads to the difficulty in controlling the height of the light shielding patterns and thus results in unacceptable quality. Several embodiments are thus provided hereinafter to describe solutions to the above problems by way of adjusting the configuration of the light shielding patterns on different panels, thus ensuring favorable quality of the display device. It should be mentioned that the embodiments below are merely exemplary and should not be construed as limitations to the invention.

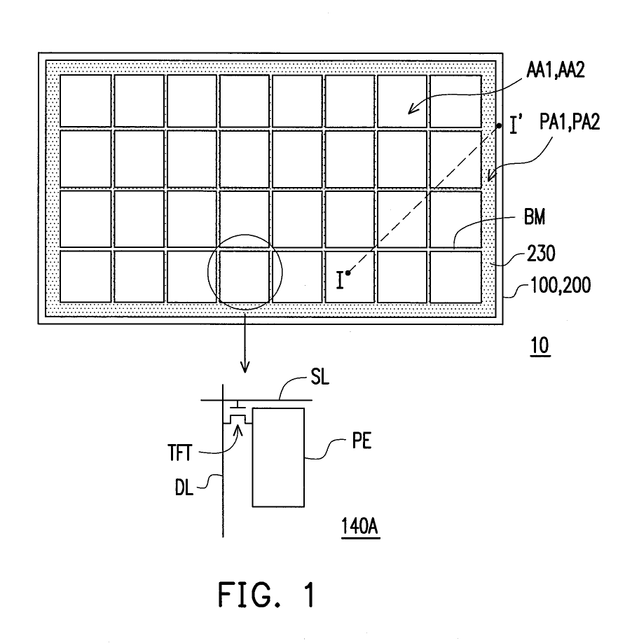

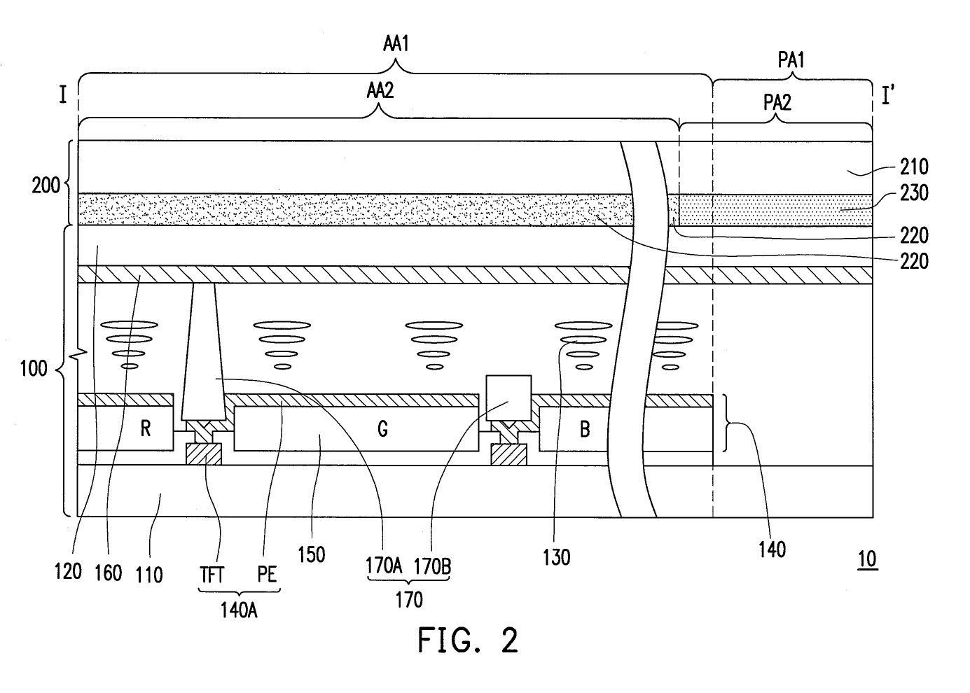

FIG. 1 is a top view illustrating a display device according to an embodiment of the invention. FIG. 2 is a cross-sectional view illustrating the display device depicted in FIG. 1 along a sectional line I-I′ according to a first embodiment of the invention. With reference to FIG. 1, the display device 10 includes a first panel 100 and a second panel 200 stacked on the first panel 100. The first panel 100 includes a first active region AA1 and a first peripheral region PA1 that surrounds the first active region AA1; the second panel 200 includes a second active region AA2 and a second peripheral region PA2 that surrounds the second active region AA2. Here, since the first panel 100 and the second panel 200 are stacked together, the first active region AA1 and the second active region AA2 shown in FIG. 1 are overlapped, and the first peripheral region PA1 and the second peripheral region PA2 shown in FIG. 1 are overlapped. All of or at least one portion of the overlapped first and second peripheral regions PA1 and PA2 is opaque.

Specifically, with reference to FIG. 1 and FIG. 2, the first panel 100 includes a first substrate 110, a second substrate 120, a display medium 130, a pixel array 140, a color filter film 150, a common electrode 160, and a first light shielding layer 170. The second substrate 120 is opposite to the first substrate 110, and the display medium 130 is located between the first substrate 110 and the second substrate 120. The pixel array 140 is disposed between the first substrate 110 and the display medium 130, and the common electrode 160 is disposed between the display medium 130 and the second substrate 120. The pixel array 140 and the common electrode 160 serve to drive the display medium 130. The color filter film 150 is combined with the pixel array 140, and the first light shielding layer 170 is located between the first substrate 110 and the second substrate 120.

In this embodiment, the first panel 100 may be a display panel for displaying images, and the display medium 130 may be a liquid crystal layer, such that the first panel 100 may be an LCD panel with the COA structure. Here, the first active region AA1 of the first panel 100 may be defined to contain the pixel array 140 that is combined with the color filter film 150. Certainly, the display medium 130 may include other display materials, such as an electrophoretic material, an electrowetting material, an organic light emitting material, and so forth. The color filter film 150 can include a red color filter pattern R, a green color filter pattern G, and a blue color filter pattern B. Alternatively, the color filter film 150 may also include a colorless pattern or a color filter pattern with other colors.

The second panel 200 includes a third substrate 210, an element layer 220, and a second light shielding layer 230. The third substrate 210 is opposite to the second substrate 120 of the first panel 100, and the element layer 220 is disposed between the third substrate 210 and the second substrate 120. The second light shielding layer 230 is disposed in the second peripheral region PA2. Here, the second light shielding layer 230 is a light shielding ring that surrounds the second active region AA2. In the second panel 200, where the element layer 220 is located defines the second active region AA2, for instance, and where the second light shielding layer 230 is located defines the second peripheral region PA2. Here, the element layer 220 may include a touch sensing layer or a parallax barrier layer, such that the display device 10 not only has the function of displaying two-dimensional images but also has the touch sensing function or the function of displaying stereoscopic images. Undoubtedly, the element layer 220 may be characterized by other functions.

As indicated in FIG. 2, the second active region AA2 is substantially smaller than the first active region AA1, and the second peripheral region PA2 is substantially larger than the first peripheral region PA1. This indicates that a projection area of the second light shielding layer 230 on the first panel 100 is overlapped with an edge of the first active region AA1, so as to partially cover the periphery of the first active region AA1. Even though there is no light shielding pattern in the first peripheral region PA1 of the first panel 100, the components in the first peripheral region PA1 are not exposed, and unnecessary light leakage on the edge of the first active region AA1 can be prevented by the disposition of the second light shielding layer 230, which is conducive to improvement of the display quality of the display device.

In particular, the pixel array 140 includes a plurality of scan lines SL, a plurality of data lines DL, a plurality of active devices TFT, and a plurality of pixel electrodes PE. The scan lines SL and the data lines DL are intersected. Each of the active devices TFT is connected to a corresponding one of the scan lines SL and a corresponding one of the data lines DL, and each of the pixel electrodes PE is connected to a corresponding one of the scan lines SL and a corresponding one of the data lines DL through one of the active devices TFT. One scan line SL, one data line DL, one active device TFT, and one pixel electrode PE can together constitute a pixel 140A, and plural pixels 140A arranged in an array can constitute the pixel array 140 described in the embodiment.

In the pixel array 140, the regions where the scan lines SL, the data lines DL, and the active devices TFT are located cannot serve to display images in most cases, and therefore these regions are often covered to prevent the display quality of images from being negatively affected. Therefore, a black matrix BM is constituted by the first light shielding layer 170 in this embodiment, and the first panel 100 can accomplish perfect display effects by configuring the black matrix BM above the scan lines SL, the data lines DL, and the active devices TFT.

To guarantee the perfect display effects, the gap between the pixel array 140 and the common electrode 160 in the first panel 100 can remain consistent by means of an appropriate support member. According to this embodiment, the first light shielding layer 170 is disposed between the pixel array 140 and the common electrode 160, and therefore the first light shielding layer 170 may act as said support member.

To be more specific, the first light shielding layer 170 may include a plurality of first light shielding patterns 170A and a plurality of second light shielding patterns 170B. The first light shielding patterns 170A and the second light shielding patterns 170B are located in the first active region AA1. In detail, the first light shielding patterns 170A substantially lean against the pixel array 140 and the common electrode 160; the second light shielding patterns 170B constitute the black matrix BM, for instance. Thereby, the first light shielding patterns 170A having the support function and the second light shielding patterns 170B having the light shielding function are formed by the same first light shielding layer 170. Since the first and second light shielding patterns 170A and 170B are formed by performing the same manufacturing process, the fabrication of the first panel 100 can be simplified.

Note that the second light shielding patterns 170B in this embodiment serve to shield light instead of acting as support members between the pixel array 140 and the common electrode 160, and thus the second light shielding patterns 170B may be shorter in height than the first light shielding patterns 170A. With reference to. FIG. 2, the second light shielding layer 230 on the second panel 200 can cover both the edge of the first active region AA1 and the first peripheral region PA1 according to this embodiment; therefore, the second light shielding layer 230 may provide the light shielding function to prevent possible light leakage on the edge of the first active region AA1 and hide the transmission wires and other components in the first peripheral region PA1. According to this embodiment, the first light shielding layer 170 need not be disposed in the first peripheral region PA1, and the display device 10 can still accomplish perfect display effects and intact appearance.

By contrast, the light shielding patterns occupying a large area of the peripheral region are required in the conventional LCD panel, and said light shielding patterns need be partially overlapped with the edge of the pixel array integrated with the color filter film. The light shielding patterns on the edge of the pixel array in the conventional LCD panel may accordingly have excessive height, such that uniform cell gaps in the conventional LCD panel cannot be provided. Since said issue is not apt to occur in this embodiment, the display device 10 can be characterized by satisfactory quality.

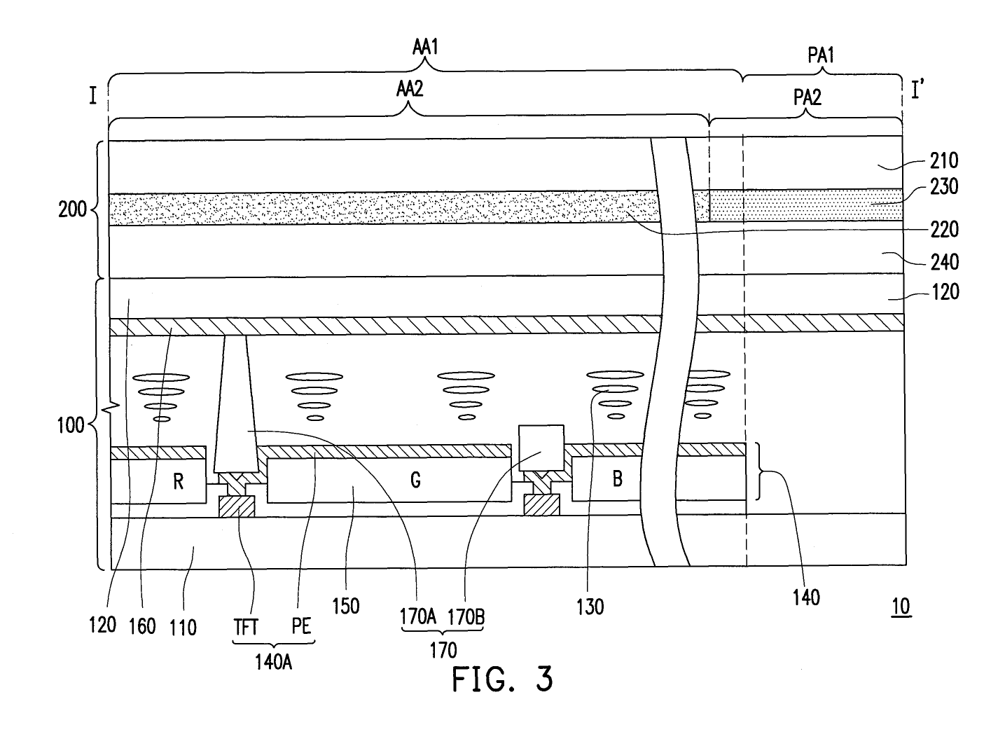

In the first embodiment, the second panel 200 has a single substrate (e.g., the third substrate 210), while the invention is not limited thereto. In another embodiment of the invention, however, the second panel 200 may have a different structural design. For instance, FIG. 3 is a cross-sectional view illustrating the display device depicted in FIG. 1 along a sectional line I-I′ according to a second embodiment of the invention. With reference to FIG. 3, the embodiment shown in FIG. 3 is substantially similar to the embodiment shown in FIG. 2, and therefore the reference numbers of the same components in these embodiments are identical. The main difference between the second embodiment and the first embodiment lies in that the second panel 200 in the second embodiment has two substrates (i.e., the third substrate 210 and the fourth substrate 240) that are opposite to each other. The fourth substrate 240 and the third substrate 210 are opposite to each other, and the fourth substrate 240 is located between the element layer 230 and the second substrate 120 of the first panel 100.

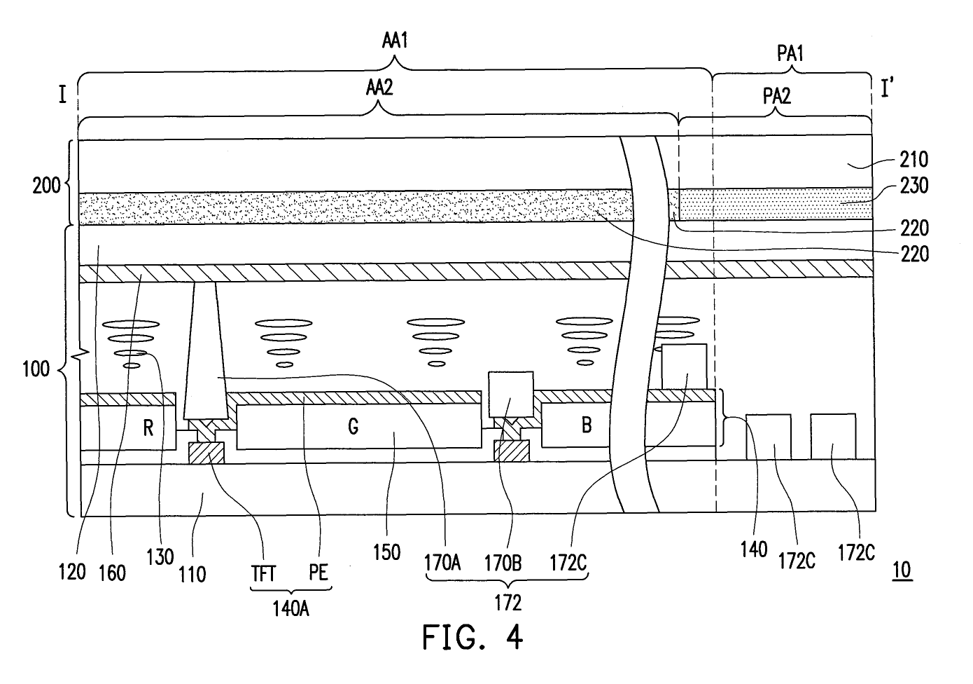

FIG. 4 is a cross-sectional view illustrating the display device depicted in FIG. 1 along a sectional line I-I′ according to a third embodiment of the invention. With reference to FIG. 4, the embodiment shown in FIG. 4 is substantially similar to the embodiment shown in FIG. 2, and therefore the reference numbers of the same components in these embodiments are identical. The main difference between the third embodiment and the first embodiment lies in that the first light shielding layer 172 in the first panel 100 further includes a plurality of discontinuous third light shielding patterns 172C that are located in the first peripheral region PA1 and overlapped with the second light shielding layer 230. Here, the first light shielding patterns 170A, the second light shielding patterns 170B, and the third light shielding patterns 172C are formed by the same film layer. Since the third light shielding patterns 172C located in the first peripheral region PA1 are not continuous and do not occupy a large area, the third light shielding patterns 172C may be shorter in height than or substantially the same in height as the first light shielding patterns 170A, i.e., the height of the third light shielding patterns 172C is not greater than that of the first light shielding patterns 170A. In this case, even though the third light shielding patterns 172C are overlapped with and stacked on the elements such as the color filter film 150 located in the first active region AA1, the conventional issue of difficulty in ensuring the uniform cell gaps (caused by the hardly controllable height of the light shielding patterns) does not arise herein. In other words, at least one portion of the third light shielding patterns 172C may be overlapped with the edge of the first active region AA1 in this embodiment, and the gap between the common electrode 160 and the pixel array 140 can still remain consistent. Moreover, the satisfactory quality of the display device 10 can still be provided.

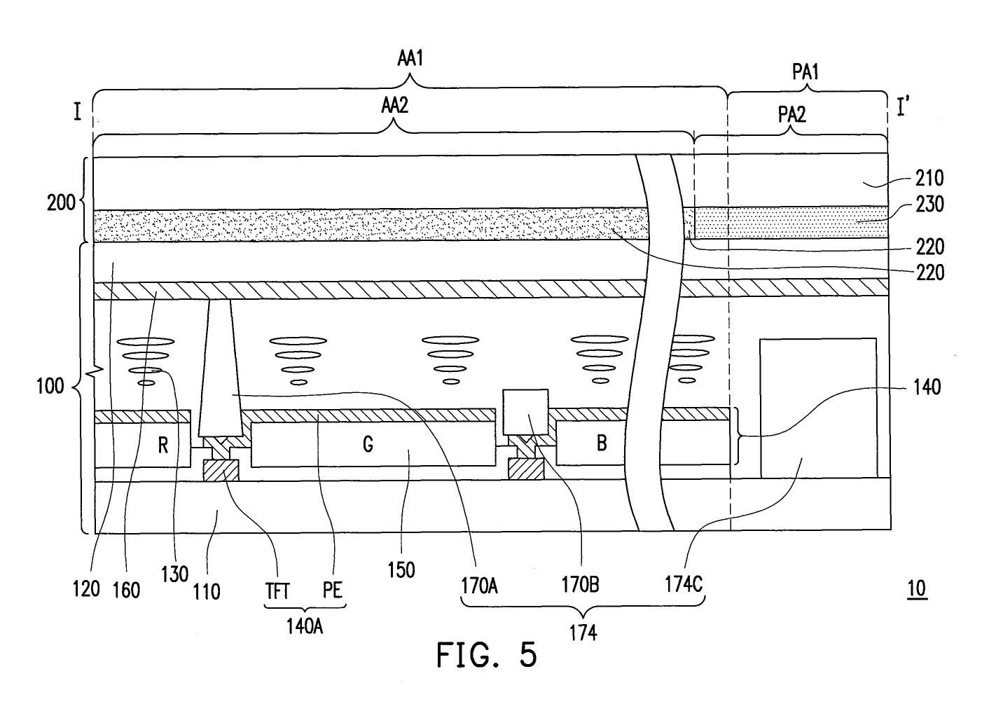

FIG. 5 is a cross-sectional view illustrating the display device depicted in FIG. 1 along a sectional line I-I′ according to a fourth embodiment of the invention. With reference to FIG. 5, the embodiment shown in FIG. 5 is substantially similar to the embodiment shown in FIG. 2, and therefore the reference numbers of the same components in these embodiments are identical. The main difference between the fourth embodiment and the first embodiment lies in that the first light shielding layer 174 in the first panel 100 further includes a continuous third light shielding pattern 174C that is located in the first peripheral region PA1 and overlapped with the second light shielding layer 230. Besides, the third light shielding pattern 174C may not be overlapped with the edge of the first active region AA1.

Since the area of the second light shielding layer 230 of the second panel 200 projected on the first panel 100 is overlapped with the edge of the first active region AA1, the second light shielding layer 230 can prevent the unnecessary light leakage possibly occurring on the edge of the first active region AA1. Accordingly, even though the third light shielding pattern 174C is not overlapped with the edge of the first active region AA1, the light leakage on the edge of the first active region AA1 can still be prevented, and the display device 10 can still achieve perfect display effects.

From another perspective, even though the third light shielding pattern 174C has a larger area in comparison with the area of the first light shielding patterns 170A and the area of the second light shielding patterns 170B, the third light shielding pattern 174C is not overlapped with the pixel array 140 that is integrated with the color filter film 150. Hence, as to the direction along which the drawings are made, the third light shielding pattern 174C is substantially located at a relatively low horizontal position. Although the height of the third light shielding pattern 174C is greater than that of the first light shielding patterns 170A, the gap between the common electrode 160 and the pixel array 140 can remain uniform, and the first panel 100 of the display device 10 can have satisfactory quality.

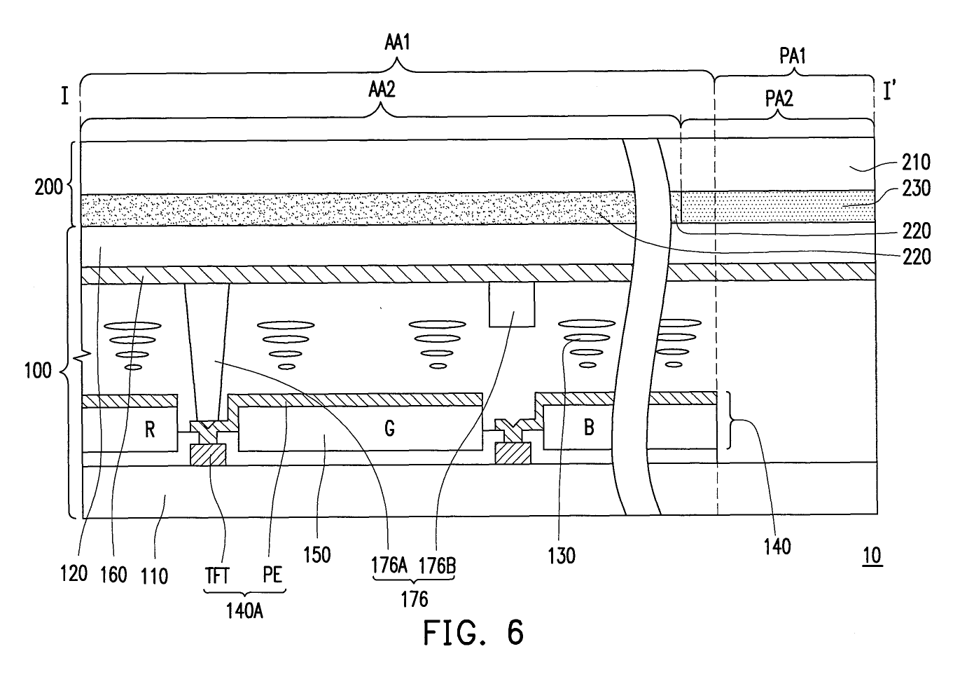

FIG. 6 is a cross-sectional view illustrating the display device depicted in FIG. 1 along a sectional line I-I′ according to a fifth embodiment of the invention. With reference to FIG. 6, the embodiment shown in FIG. 6 is substantially similar to the embodiment shown in FIG. 2, and therefore the reference numbers of the same components in these embodiments are identical. The main difference between the fifth embodiment and the first embodiment lies in that the first light shielding layer 176 containing the first light shielding patterns 176A and the second light shielding patterns 176B are configured on the second substrate 120, for instance, such that the second light shielding patterns 176B are located between the display medium 130 and the common electrode 160. At the same time, the first light shielding patterns 176A lean against the pixel array 140 and the common electrode 160. According to the design described in the fifth embodiment and the first embodiment, the first light shielding layer (170, 176) in the first panel 100 is not limited to be configured on the first substrate 110 or the second substrate 120, and the first light shielding layer 176 shown in FIG. 6 may further include the third light shielding patterns 172C shown in FIG. 4 or the third light shielding pattern 174C shown in FIG. 5. In this case, the gap between the common electrode 160 and the pixel array 140 of the first panel 100 can still be uniform, and the display device 10 is thus allowed to have satisfactory quality. This to a great extent resolves the issue of difficulty in ensuring the uniform cell gaps in a conventional design.

In light of the foregoing, the panel having the display function and the panel having a different function are stacked together in the invention, so as to allow the display device to provide multiple functions. Each of the panels respectively has a light shielding layer thereon for performing the light shielding function and especially for covering the peripheral region of the display device. When the panel for displaying images has the COA structure, the light shielding layer on the other panel may serve to cover the peripheral region and the edge of the active region; therefore, the light shielding patterns that occupy a large area and overlap the pixel array need not be formed in the peripheral region and the edge of the active region in the panel for displaying images. As a result, the problem of the hardly manageable gap uniformity between the light shielding patterns and the pixel array can be effectively prevented.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A display device comprising:
a first panel having a first active region and a first peripheral region surrounding the first active region, the first panel comprising:
a first substrate;
a second substrate opposite to the first substrate;
a display medium disposed between the first substrate and the second substrate;
a pixel array disposed on the first substrate and located between the first substrate and the display medium for driving the display medium;
a color filter film combined with the pixel array;
a common electrode disposed on the second substrate and located between the display medium and the second substrate;
a first light shielding layer disposed between the first substrate and the second substrate and comprising a plurality of first light shielding patterns and a plurality of second light shielding patterns, the second light shielding patterns being located in the first active region and forming a black matrix, the first light shielding patterns substantially leaning against the pixel array and the common electrode, the second light shielding patterns being shorter in height than the first light shielding patterns; and
a second panel stacked on the first panel, the second panel having a second active region and a second peripheral region surrounding the second active region, the second active region being substantially smaller than the first active region, the second peripheral region being substantially larger than the first peripheral region, the second panel comprising:
a third substrate opposite to the second substrate;
an element layer disposed between the third substrate and the second substrate; and
a second light shielding layer disposed in the second peripheral region.

2. The display device as recited in claim 1, wherein a projection area of the second light shielding layer on the first panel is overlapped with an edge of the first active region.

3. The display device as recited in claim 1, wherein the second light shielding layer comprises a light shielding ring surrounding the second active region.

4. The display device as recited in claim 1, wherein the pixel array comprises a plurality of scan lines, a plurality of data lines, a plurality of active devices, and a plurality of pixel electrodes, the scan lines and the data lines are intersected, each of the active devices is connected to a corresponding one of the scan lines and a corresponding one of the data lines, each of the pixel electrodes is connected to a corresponding one of the scan lines and a corresponding one of the data lines through one of the active devices, and the black matrix is located above the scan lines, the data lines, and the active devices.

5. The display device as recited in claim 1, wherein the first light shielding layer further comprises a plurality of discontinuous third light shielding patterns located in the first peripheral region, and the third light shielding patterns and the second light shielding layer are overlapped.

6. The display device as recited in claim 1, wherein the first light shielding layer further comprises a third light shielding pattern located in the first peripheral region.

7. The display device as recited in claim 1, wherein the first light shielding layer is disposed on the first substrate, and the second light shielding patterns are located between the display medium and the pixel array.

8. The display device as recited in claim 1, wherein the first light shielding layer is disposed on the second substrate, and the second light shielding patterns are located between the display medium and the common electrode.

9. The display device as recited in claim 1, wherein the element layer of the second panel comprises a touch sensing layer or a parallax barrier layer.

10. The display device as recited in claim 1, wherein the second panel further comprises a fourth substrate opposite to the third substrate and the fourth substrate is located between the element layer and the second substrate of the first panel.
